(19) United States
(12) Patent Application Publication
(10) Pub. No.: US 2008/0025384 A1
(43) Pub. Date: Jan. 31, 2008

(54) METHOD AND APPARATUS FOR FREQUENCY DOMAIN EXUALIZATION BASED UPON A DECISION FEEDBACK IN A TDS-OFDM RECEIVER

(75) Inventors: Qin Liu, Fremont, CA (US); Dinesh Venkatachalam, Fremont, CA (US)

Correspondence Address: FRANKLIN (LIN) YANG, 91 CANTERBURY GATE, LYNBROOK, NY, 11563, US

(73) Assignee: LEGEND SILICON, Fremont, CA (US)

(21) Appl. No.: 11/550,342

(22) Filed: Oct. 17, 2006

Related U.S. Application Data
(60) Provisional application No. 60/820,319, filed on Jul. 25, 2006.

(51) Int. Cl. H03H 7/30; H04K 1/10; H04L 27/06

(52) U.S. Cl. 375/229; 375/260; 375/340

(57) ABSTRACT

A device for equalization adapted for receiving a symbol and a channel frequency response is provided. The device includes a slicer for delimiting the channel frequency response to a sliced channel frequency response based upon a signal constellation; and a divider for dividing the received symbol using the sliced channel frequency response as the divider, with a resultant quotient of the divider as a reference point for future received symbols.

### REFERENCE TO RELATED APPLICATIONS

This application claims an invention which was disclosed in Provisional Application No. 60/820,319, filed Jul. 25, 2006 entitled “Receiver For An LDPC based TDS-OFDM Communication System”. The benefit under 35 USC §119(e) of the United States provisional application is hereby claimed, and the aforementioned application is hereby incorporated herein by reference.

### FIELD OF THE INVENTION

The present invention relates generally to communication devices. More specifically, the present invention relates to a frequency-domain equalization based decision feedback in a TDS-OFDM receiver.

### BACKGROUND

OFDM (Orthogonal frequency-division multiplexing) is known. U.S. Pat. No. 3,488,445 to Chang describes an apparatus and method for frequency multiplexing of a plurality of data signals simultaneously on a plurality of mutually orthogonal carrier waves such that overlapping, but band-limited, frequency spectra are produced without casing interchannel and intersymbol interference. Amplitude and phase characteristics of narrow-band filters are specified for each channel in terms of their symmetries alone. The same signal protection against channel noise is provided as though the signals in each channel were transmitted through an independent medium and intersymbol interference were eliminated by reducing the data rate. As the number of channels is increased, the overall data rate approaches the theoretical maximum.

OFDM transceivers are known. U.S. Pat. No. 5,282,222 to Fattouche et al describes a method for allowing a number of wireless transceivers to exchange information (data, voice or video) with each other. A first frame of information is multiplexed over a number of wideband frequency bands at a first transceiver, and the information transmitted to a second transceiver. The information is received and processed at the second transceiver. The information is differentially encoded using phase shift keying. In addition, after a pre-selected time interval, the first transceiver may transmit again. During the preselected time interval, the second transceiver may exchange information with another transceiver in a time duplex fashion. The processing of the signal at the second transceiver may include estimating the phase differential of the transmitted signal and pre-distorting the transmitted signal. A transceiver includes an encoder for encoding information, a wideband frequency division multiplexer for multiplexing the information onto wideband frequency voice channels, and a local oscillator for upconverting the multiplexed information. The apparatus may include a processor for applying a Fourier transform to the multiplexed information to bring the information into the time domain for transmission.

Using PN (pseudo-noise) as the guard interval in an OFDM is known. U.S. Pat. No. 7,072,289 to Yang et al describes a method of estimating timing of at least one of the beginning and the end of a transmitted signal segment in the presence of time delay in a signal transmission channel. Each of a sequence of signal frames is provided with a pseudo-noise (PN) m-sequences, where the PN sequences satisfy selected orthogonality and closures relations. A convolution signal is formed between a received signal and the sequence of PN segments and is subtracted from the received signal to identify the beginning and/or end of a PN segment within the received signal. PN sequences are used for timing recovery, for carrier frequency recovery, for estimation of transmission channel characteristics, for synchronization of received signal frames, and as a replacement for guard intervals in an OFDM context.

Using PN sequence as guard intervals for an estimation of channel frequency response is known. However, this estimation may not be accurate due to various reasons. This estimation is not accurate due to channel delay after transmission. Due to channel delay, the guard interval may contain symbol or payload information from the immediate previous frame or packet. By the same token, part of the information contained in the transmitted guard interval may be delayed into the predetermined payload regions. Therefore, a self-correcting feedback loop is desired. Therefore, it is desirous to further improve this channel estimation be means of the feedback loop.

### SUMMARY OF THE INVENTION

A channel estimation using a guard interval and a derivative of the same as a basis for estimation for subsequent frames is provided.

A channel estimation using at least one guard interval a decision feedback is provided.

A channel estimation having guard interval comprising PN (pseudo-noise) and using received PN (pseudo-noise) sequence is provided.

A channel estimation using the received PN (pseudo-noise) sequence as a guard interval and a derivative of the same as a basis for estimation for subsequent frames is provided.

A channel estimation using the received PN (pseudo-noise) sequence as a guard interval and a decision feedback is provided.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of a receiver in accordance with some embodiments of the invention.

FIG. 2 is an example of a simplified receiver.

FIG. 3 is a prior art signal relationship.

FIG. 4 is an example of a diagram depicting a feedback loop of the present invention.

FIG. 5 is an example of a signal constellation according to the present invention.

FIG. 6 is an example of a graph according to the present invention.

FIG. 7 is an example of a series of frames according to the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to an estimate of channel characteristic based upon a decision feedback. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that the embodiments of the invention described herein may be comprised of one or more conventional processors and unique stored program instructions that control the one or more processors to implement, in conjunction with certain non-processor circuits, some, most, or all of the functions of estimation of a channel based upon a decision feedback described herein. The non-processor circuits may include, but are not limited to, a radio receiver, a radio transmitter, signal drivers, clock circuits, power source circuits, and user input devices. As such, these functions may be interpreted as steps of a method to perform estimating a channel based upon a decision feedback. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

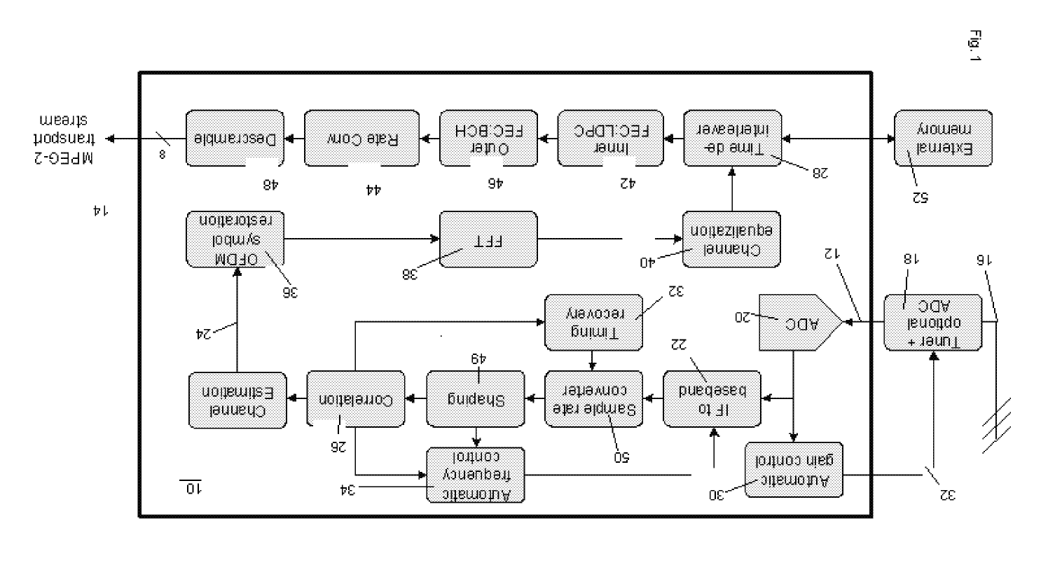

Referring to FIG. 1, a receiver 10 for implementing a LDPC based TDS-OFDM communication system is shown. In other words, FIG. 1 is a block diagram illustrating the functional blocks of an LDPC based TDS-OFDM receiver 10. Demodulation herein follows the principles of TDS-OFDM modulation scheme. Error correction mechanism is based on LDPC. The primary objectives of the receiver 10 is to determine from a noise-perturbed system, which of the finite set of waveforms have been sent by a transmitter and using an assortment of signal processing techniques reproduce the finite set of discrete messages sent by the transmitter.

The block diagram of FIG. 1 illustrates the signals and key processing steps of the receiver 10. It is assumed the input signal 12 to the receiver 10 is a down-converted digital signal. The output signal 14 of receiver 10 is a MPEG-2 transport stream. More specifically, the RF (radio frequency) input signals 16 are received by an RF tuner 18 where the RF input signals are converted to low-IF ( ) or zero-IF signals 12. The low-IF or zero-IF signals 12 are provided to the receiver 10 as analog signals or as digital signals (through an optional analog-to-digital converter 20).

In the receiver 10, the IF signals are converted to base-band signals 22. TDS-OFDM (Time domain synchronous-Orthogonal frequency-division multiplexing) demodulation is then performed according to the parameters of the LDPC (low-density parity-check) based TDS-OFDM modulation scheme. The output of the channel estimation 24 and correlation block 26 is sent to a time de-interleaver 28 and then to the forward error correction block. The output signal 14 of the receiver 10 is a parallel or serial MPEG-2 transport stream including valid data, synchronization and clock signals. The configuration parameters of the receiver 10 can be detected or automatically programmed, or manually set. The main configurable parameters for the receiver 10 include: (1) Sub carrier modulation type: QPSK, 16QAM, 64QAM; (2) FEC rate: 0.4, 0.6 and 0.8; (3) Guard interval: 420 or 945 symbols; (4) Time de-interleaver mode: 0.240 or 720 symbols; (5) Control frames detection; and (6) Channel bandwidth: 6, 7, and 8 MHz.

The functional blocks of the receiver 10 are described as follows.

Automatic gain control (AGC) block 30 compares the input digitized signal strength with a reference. The difference is filtered and the filter value 32 is used to control the gain of the amplifier 18. The analog signal provided by the tuner 12 is sampled by an ADC 20. The resulting signal is centered at a lower IF. For example, sampling a 36 MHz IF signal at 30.4 MHz results in the signal centered at 5.6 MHz. The IF to Baseband block 22 converts the lower IF signals to a complex signal in the baseband. The ADC 20 uses a fixed sampling rate. Conversion from this fixed sampling rate to the OFDM sample rate is achieved using the interpolator in block 22. The timing recovery block 32 computes the timing error and filters the error to drive a Numerically Controlled Oscillator (not shown) that controls the sample timing correction applied in the interpolator of the sample rate converter.

There can be frequency offsets in the input signal 12. The automatic frequency control block 34 calculates the offsets and adjusts the IF to baseband reference IF frequency. To improve capture range and tracking performance, frequency control is done in two stages: coarse and fine. Since the transmitted signal is square root raised cosine filtered, the received signal will be applied with the same function. It is known that signals in a TDS-OFDM system include a PN sequence preceding the IDFT symbol. By correlating the locally generated PN with the incoming signal, it is easy to find the correlation peak (so the frame start can be determined) and other synchronization information such as frequency offset and timing error. Channel time domain response is based on the signal correlation previously obtained. Frequency response is taking the FFT of the time domain response.

In TDS-OFDM, a PN sequence replaces the traditional cyclic prefix. It is thus necessary to remove the PN sequence and restore the channel spreaded OFDM symbol. Block 36 reconstructs the conventional OFDM symbol that can be one-tap equalized. The FFT block 38 performs a 3780 point FFT. Channel equalization 40 is carried out to the FFT 38 transformed data based on the frequency response of the channel. De-rotated data and the channel state information are sent to FEC for further processing.

In the TDS-OFDM receiver 10, the time-deinterleaver 28 is used to increase the resilience to spurious noise. The time-deinterleaver 28 is a convolutional de-interleaver which needs a memory with size B*(B−1)*M/2, where B is the number of the branch, and M is the depth. For the TDS-OFDM receiver 10 of the present embodiment, there are two modes of time-deinterleavering. For mode 1, B=52, M=240, and for mode 2, B=52, M=720.

The LDPC decoder 42 is a soft-decision iterative decoder for decoding, for example, a Quasi-Cyclic Low Density Parity Check (QC-LDPC) code provided by a transmitter (not shown). The LDPC decoder 42 is configured to decode at 3 different rates (i.e. rate 0.4, rate 0.6 and rate 0.8) of QC_LDPC codes by sharing the same piece of hardware. The iteration process is either stopped when it reaches the specified maximum iteration number (full iteration), or when the detected error is free during error detecting and correcting process (partial iteration).

The TDS-OFDM modulation/demodulation system is a multi-rate system based on multiple modulation schemes (QPSK, 16QAM, 64QAM), and multiple coding rates (0.4, 0.6, and 0.8), where QPSK stands for Quad Phase Shift Keying and QAM stands for Quadrature Amplitude Modulation. The output of BCH decoder is bit by bit. According to different modulation scheme and coding rates, the rate conversion block combines the bit output of BCH decoder to bytes, and adjusts the speed of byte output clock to make the receiver 10's MPEG packets outputs evenly distributed during the whole demodulation/decoding process.

The BCH decoder 46 is designed to decode BCH (762, 752) code, which is the shortened binary BCH code of BCH (1023, 1013). The generator polynomial is x̂10+x̂3+1.

Since the data in the transmitter has been randomized using a pseudo-random (PN) sequence before BCH encoder (not shown), the error corrected data by the LDPC/BCH decoder 46 must be de-randomized. The PN sequence is generated by the polynomial 1×x¹⁴+x¹⁵, with initial condition of 100101010000000. The de-scrambler/de-randomizer 48 will be reset to the initial condition for every signal frame. Otherwise, de-scrambler/de-randomizer 48 will be free running until reset again. The least significant 8-bit will be XORed with the input byte stream.

The data flow through the various blocks of the modulator is as follows. The received RF information 16 is processed by a digital terrestrial tuner 18 which picks the frequency bandwidth of choice to be demodulated and then downconverts the signal 16 to a baseband or low-intermediate frequency. This downconverted information 12 is then converted to the Digital domain through an analog-to-digital data converter 20.

The baseband signal after processing by a sample rate converter 50 is converted to symbols. The PN information found in the guard interval is extracted and correlated with a local PN generator to find the time domain impulse response. The FFT of the time domain impulse response gives the estimated channel response. The correlation 26 is also used for the timing recovery 32 and the frequency estimation and correction of the received signal. The OFDM symbol information in the received data is extracted and passed through a 3780 FFT 38 to obtain the symbol information back in the frequency domain. Using the estimated channel estimation previously obtained, the OFDM symbol is equalized and passed to the FEC decoder.

At the FEC decoder, the time-deinterleaver block 28 performs a deconvolution of the transmitted symbol sequence and passes the 3780 blocks to the inner LDPC decoder 42. The LDPC decoder 42 and BCH decoders 46 which run in a serial manner take in exactly 3780 symbols, remove the 36 TPS symbols and process the remaining 3744 symbols and recover the transmitted transport stream information. The rate conversion 44 adjusts the output data rate and the de-randomizer 48 reconstructs the transmitted stream information. An external memory 52 coupled to the receiver 10 provides memory thereto on a predetermined or as needed basis.

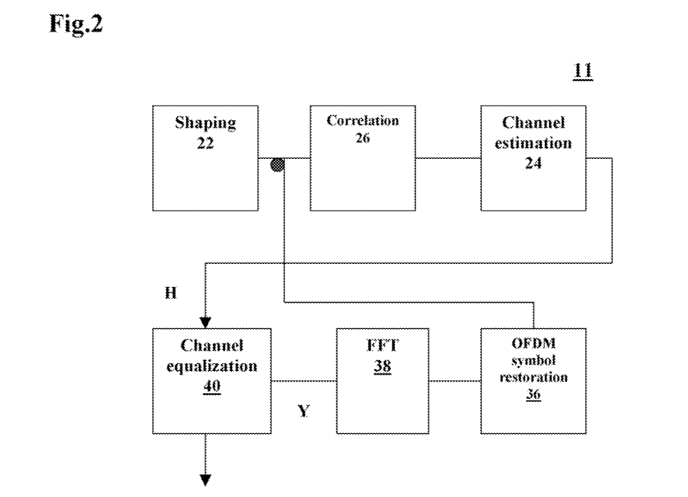

Referring to FIG. 2, a receiver 11, which is a simplified version of the receiver of FIG. 1 is shown. Shaping block 22 is coupled to correlation block 26. Correlation block 26 in turn is coupled to channel estimation block 24, which outputs a channel response H subject to channel equalization by channel equalization block 40. Shaping block 22 is also coupled to OFDM symbol restoration block 36. The output of OFDM symbol restoration block 36 is the time domain value y of a transmitted symbol. The transmitted symbol y passes through Fourier transform block 38 to be transformed into frequency domain value Y that is used by channel equalization block 40.

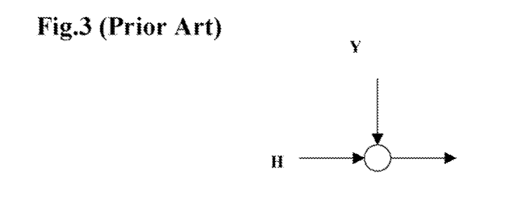

Referring to FIG. 3, a prior art means for channel estimation is shown. The known channel frequency response H is used to divide the transformed symbol Y to obtain fixed channel estimation. By way of an example in a TDS-OFDM system, equalization is done by dividing the received symbol Y in the frequency domain (after a frequency domain transform) with channel frequency response H. However, channel frequency response H may not always represent the current true frequency response. Typically the channel frequency response H is estimated from known guard intervals such as PN sequences. In other words, channel frequency response H is estimated from at least one known guard interval. This estimation is not accurate due to channel delay after transmission. Due to channel delay, the guard interval may contain symbol or payload information from the immediate previous frame or packet. By the same token, part of the information contained in the transmitted guard interval may be delayed into the predetermined payload regions. Therefore, a self-correcting feedback loop is desired.

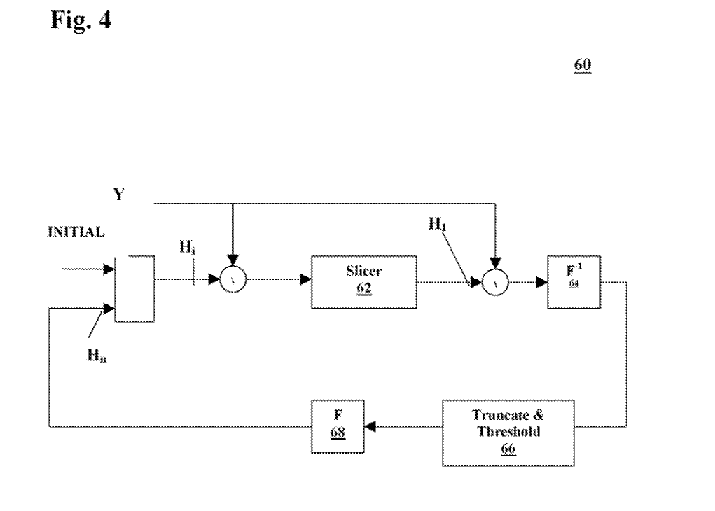

Referring to FIG. 4, a block diagram 60 depicting a feedback loop which improves upon the exiting channel response is shown. As such, the equalization needs to be further improved. This invention contemplates a way of equalization based on decision feedback. Therefore, an initial H value is obtained as follows. Suppose y is the received symbol, and Y is the FFT of y, Hᵢ is the channel frequency response (initial estimate). Symbol constellation slicer 62 decision is made on Y/H. In other words, slicer 62 acts upon Y/H. The resultant new channel estimation is obtained as:

H₁=Y/slice(Y/H) (1)

By taking the inverse FFT 64 of H₁, truncating 66 to channel profile length, and thresholding 66 the noise floor by truncate & threshold block 66, then frequency transforming by a 68 to H₂, a new estimation of channel Hₙ is obtained. This new estimation is used for next frame, hence the decision feedback.

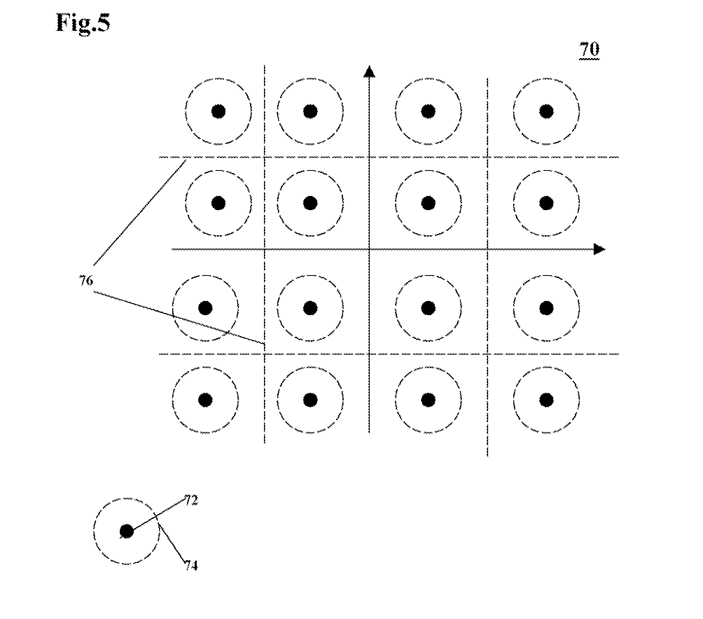

Referring to FIG. 5, a signal constellation mapping graph 70 is shown. As can be seen, under ideal or good conditions such as the additive white Gaussian noise (AWGN) channel model, points 72 should be a good representation. However in practice, point 72 typically falls within a neighborhood 74 of the AWGN point 72. As such, constellation mapping can be done in such a way that by drawing horizontal and vertical lines 76, a series of rectangles are defined. Any points falling within the resultant rectangle should be given the AWGN point value or an averaged value of all the points within the reactangle, thereby obtaining a set of fixed and simplified values for computational purposes.

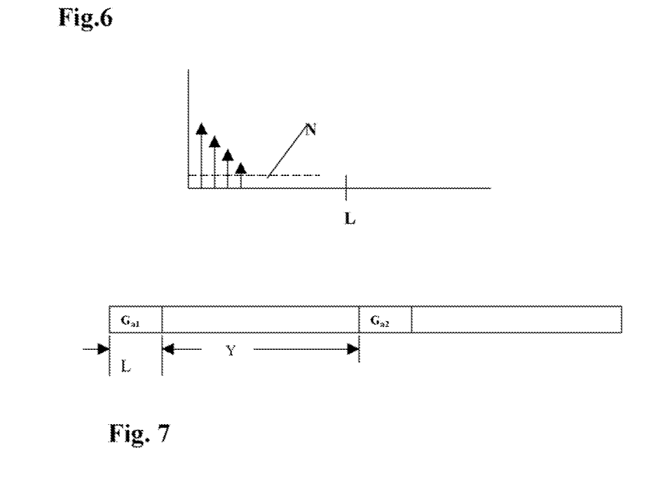

Referring to FIG. 6, a chart of the present invention is shown. Note that only the guard interval length L is used for computational purposes of the present invention. Further, note noise level N that is being eliminated by the noise elimination function of truncate & threshold by block 66.

Referring to FIG. 7, a series of frames is shown. Similarly, only information contained within length L of the guard interval is used.

It is noted that the present invention contemplates using the PN sequence disclosed in U.S. Pat. No. 7,072,289 to Yang et al which is hereby incorporated herein by reference.

A method for use in a used in a device for equalization adapted for receiving a symbol and a channel frequency response is provided. The method comprises the steps of: using a slicer for delimiting the channel frequency response to a sliced channel frequency response based upon a signal constellation; and dividing the received symbol using the sliced channel frequency response as the divider, with a resultant quotient of the divider as a reference point for future received symbols.

A device for equalization adapted for receiving a symbol and a channel frequency response is provided. The device includes a slicer for delimiting the channel frequency response to a sliced channel frequency response based upon a signal constellation; and a divider for dividing the received symbol using the sliced channel frequency response as the divider, with a resultant quotient of the divider as a reference point for future received symbols.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A device for equalization adapted for receiving a symbol and a channel frequency response, the device comprising:
a slicer for delimiting the channel frequency response to a sliced channel frequency response based upon a signal constellation; and
a divider for dividing the received symbol using the sliced channel frequency response as the divider, with a resultant quotient of the divider as a reference point for future received symbols.

2. The device of claim 1 further comprising a truncater for further limiting the sliced information to a specific time period relating to a guard area between symbols.

3. The device of claim 2, wherein the guard area comprises a PN (pseudo-noise) sequence.

4. The device of claim 1 further comprising a threshold limiter for limiting a noise.

5. The device of claim 1 further comprising an inverse Fourier transformer for transferring the quotient into time domain for a truncation to a predetermined channel length and a threshold for limiting noise.

6. The device of claim 1, wherein the predetermined channel length is about L.

7. The device of claim 1 further comprising a Fourier transformer for transferring the inversely transformed received symbol back to frequency domain.

8. A method used in a device for equalization adapted for receiving a symbol and a channel frequency response, the method comprising the steps of:
using a slicer for delimiting the channel frequency response to a sliced channel frequency response based upon a signal constellation; and
dividing the received symbol using the sliced channel frequency response as the divider, with a resultant quotient of the divider as a reference point for future received symbols.

9. The method of claim 8 further comprising truncating the sliced information to a specific time period relating to a guard area between symbols.

10. The method of claim 9, wherein the guard area comprises a PN (pseudo-noise) sequence.

11. The method of claim 8 further comprising providing a threshold limiter for limiting a noise.

12. The method of claim 8 further comprising providing an inverse Fourier transformer for transferring the quotient into time domain for a truncation to a predetermined channel length and a threshold for limiting noise.

13. The method of claim 8, wherein the predetermined channel length is about L.

14. The method of claim 8 further comprising providing a Fourier transformer for transferring the inversely transformed received symbol back to frequency domain.
